(19) United States
(12) Patent Application Publication
(10) Pub. No.: US 2026/0177638 A1
(43) Pub. Date: Jun. 25, 2026

(54) HARDWARE FAULT MONITORING CIRCUIT

(71) Applicant: Eaton Intelligent Power Limited, Dublin 4 (IE)

(72) Inventors: Ravi Patel, Gujarat (IN); Pratik Katolkar, Pune (IN); Derek Dougherty, Fruitport, MI (US); Sachin Patil, Pune (IN); Sauradeep Datta, Pune (IN)

(73) Assignee: Eaton Intelligent Power Limited, Dublin 4 (IE)

(21) Appl. No.: 19/419,560

(22) Filed: Dec. 15, 2025

(30) Foreign Application Priority Data
Dec. 19, 2024 (IN) 202411100847

(51) Int. Cl. G01R 31/42; G01R 19/165; G01R 31/34

(52) U.S. Cl. CPC G01R 31/42; G01R 19/16547; G01R 19/16576; G01R 31/34

(57) ABSTRACT

A fault detection circuit provides hardware-based fault detection to a system including power electronics. The fault detection circuit includes sensor interfaces and scaling amplifiers to scale sensor outputs for comparison to reference voltages at respective comparators. Logic levels output from the comparators are received at logic gate circuits and used to determine a master logic level that is used to control a gate driver, thereby directing response to the detection of a fault by the fault detection circuit. The fault detection circuit can be included in a motor controller such as a motor controller of a hydraulic power pack.

### CROSS-REFERENCE TO RELATED APPLICATION

This application claims the benefit of Indian Application Serial No. 202411100847, filed Dec. 19, 2024, the disclosure of which is hereby incorporated by reference in its entirety.

### BACKGROUND

The reliability of power electronics such as inverters is becoming increasingly important as a result of electrification in, for example, automotive or aerospace applications. Faults can impact the power electronics and systems relying on them, causing inefficiency, component damage, system shutdown, or other such effects. Existing fault detection is typically software based, thus being susceptible to controller failures such as brownout, corruption of software, security vulnerabilities, and lacks failsafes that may be necessary for critical components, for example in aerospace. Alternatively, additional hardware such as complex programmable logic devices (CPLD) or field programmable gate arrays (FPGA) can be used for fault monitoring, however these are typically large, costly, and/or add significantly to power consumption.

### SUMMARY

The present disclosure is directed to a hardware fault monitoring circuit for power electronics, and electronics such as motor controller units including the hardware fault monitoring circuit.

By providing a simple hardware logic system for detecting faults, embodiments of the present disclosure can provide a secure, reliable failsafe for detecting and responding to faults in power electronics such as inverters, motor control units, and the like, for example in applications such as a hydraulic power pack motor control units while having high reliability and low cost and power consumption. The hardware fault monitoring system can provide more precise and faster responses to faults when compared to, for example, controller-based fault detection. The hardware fault monitoring circuit can be configured to exhibit hysteresis characteristics, preventing instability from variations in sensor readings, noise, operations close to fault thresholds, transient effects, or the like.

Hardware fault monitoring circuits according to embodiments can reduce the frequency of controller failures, thereby increasing the reliability of modules or devices where controllers tend to be among the components thereof having the lowest mean times between failure, such as in hydraulic power packs.

In an embodiment, a fault monitoring circuit includes one or more sensor interfaces and one or more scaling amplifiers. Each scaling amplifier is connected to a respective sensor interface of the one or more sensor interfaces. Each of the one or more scaling amplifiers is configured to output a scaled voltage proportional to a voltage received from the respective sensor interface. The fault monitoring circuit further includes one or more comparators each configured to receive the scaled voltage from one of the one or more scaling amplifiers and to output a logic level based on the scaled voltage. The logic level is indicative of health or a fault. The fault monitoring circuit further includes a logic gate circuit configured to receive the logic level of each of the one or more comparators and to output a master logic level signal.

In an embodiment, a method includes receiving one or more voltages at a respective one or more sensor interfaces. The method further includes scaling the received one or more voltages using a respective one or more scaling amplifier circuits to output one or more scaled voltages. The method additionally includes comparing the one or more scaled voltages to a respective one or more reference voltages using a respective one or more comparators to output a respective one or more logic levels. The method also includes determining a master logic level using one or more logic gate circuits based on the one or more logic levels and operating a gate driver based on the master logic level.

A variety of additional inventive aspects will be set forth in the description that follows. The inventive aspects can relate to individual features and to combinations of features. It is to be understood that both the forgoing general description and the following detailed description are exemplary and explanatory only and are not restrictive of the broad inventive concepts upon which the embodiments disclosed herein are based.

### BRIEF DESCRIPTION OF THE DRAWINGS

The accompanying drawings, which are incorporated in and constitute a part of the description, illustrate several aspects of the present disclosure. A brief description of the drawings is as follows:

FIG. 1 shows a schematic of a fault monitoring circuit according to an embodiment.

FIG. 2 shows a circuit diagram for examples of a scaling amplifier and a comparator according to an embodiment.

FIG. 3 shows a circuit diagram for an example fault detection logic circuit according to an embodiment.

FIG. 4 shows a method of fault detection according to an embodiment.

FIG. 5 shows a schematic of a hydraulic power pack according to an embodiment.

### DETAILED DESCRIPTION

Reference will now be made in detail to exemplary aspects of the present disclosure that are illustrated in the accompanying drawings. Wherever possible, the same reference numbers will be used throughout the drawings to refer to the same or like parts.

Hardware monitoring of faults using fault monitoring circuits according to embodiments can provide secure and reliable detection of and response to faults in power electronics such as inverters, motor control units, hydraulic power packs, and the like. Hardware monitoring can provide such fault detection and response with high reliability and low cost and power consumption. Hardware fault monitoring can also provide more precise and faster responses to faults when compared to, for example, controller-based fault detection.

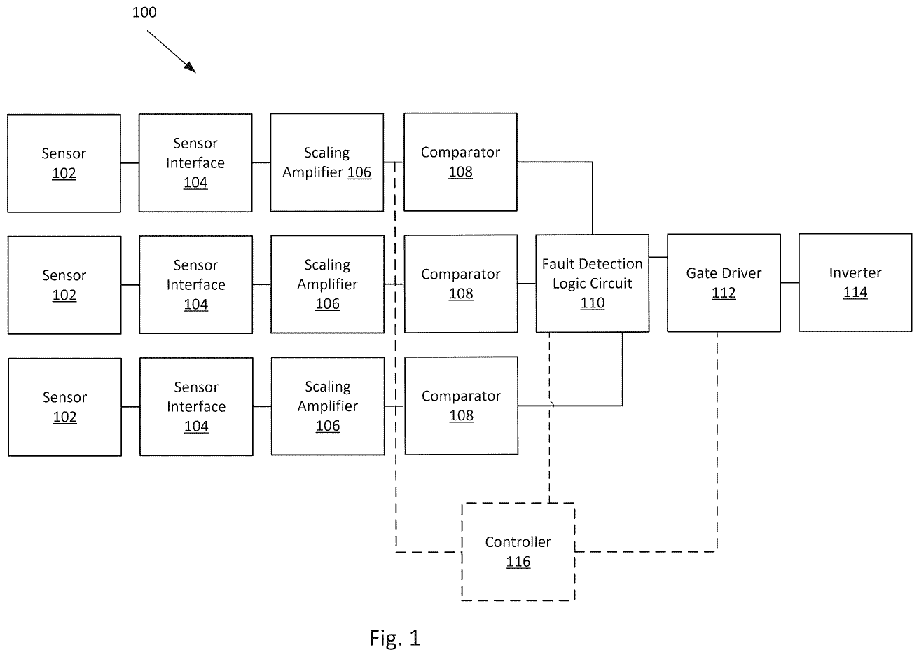

FIG. 1 shows a schematic of a fault monitoring circuit according to an embodiment. Fault monitoring circuit 100 includes sensors 102, sensor interfaces 104, scaling amplifiers 106, comparators 108, and fault detection logic circuit 110. Fault detection logic circuits 110 can connect to a gate driver 112. The gate driver 112 can control operation of an inverter 114. In an embodiment, controller 116 can optionally further be included in the fault monitoring circuit 100.

Fault monitoring circuit 100 is configured to provide hardware-based detection of faults in power electronics, such as inverter 114, based on inputs from the sensors 102. Fault monitoring circuit 100 can direct shutdown of electronics when a fault is detected, for example through operation of gate driver 112 based on a master logic level signal output by the fault monitoring circuit 100. The fault monitoring circuit 100 can optionally be combined with controller 116 providing software-based fault detection in parallel with the fault detection performed by fault monitoring circuit 100.

Sensors 102 are sensors configured to provide a voltage signal indicative of a measured condition. The conditions measured by respective sensors 102 can be any suitable condition indicative of a fault in the system monitored by fault monitoring circuit 100. Non-limiting examples of conditions measured by respective sensors 102 can include current, voltage, temperature, or pressure. In an embodiment, at least some of sensors 102 can be positioned on a circuit board of a device to be monitored by the fault monitoring circuit 100. In an embodiment, sensors 102 can be sensors integrally included in a circuit board of the device. In an embodiment, sensors 102 are discrete sensors applied to the circuit board of the device. In an embodiment, the sensors 102 include at least one voltage sensor, at least one current sensor, and/or at least one temperature sensor. The sensors 102 can further include a pressure sensor, or any other suitable type of sensor capable of measuring a condition indicative of a fault. While three sensors 102 are shown in FIG. 1, more or fewer sensors 102 can be provided to measure conditions within the system monitored by fault monitoring circuit 100.

Sensor interfaces 104 are each configured to receive a signal from a respective one of sensors 102 and provide the signal to a respective one of the scaling amplifiers 106. Sensor interfaces 104 can be, for example, wires or any other suitable electrical connection or combination thereof connecting outputs of the sensors 102 to the scaling amplifiers 106. A sensor interface 104 can be provided for each of sensors 102 used to determine faults. Each sensor interface 104 can connect to a respective scaling amplifier 106. While three sensor interfaces 104 are shown in FIG. 1, more or fewer sensor interfaces 104 can be provided to provide a sensor interface 104 corresponding to each of the sensors 102.

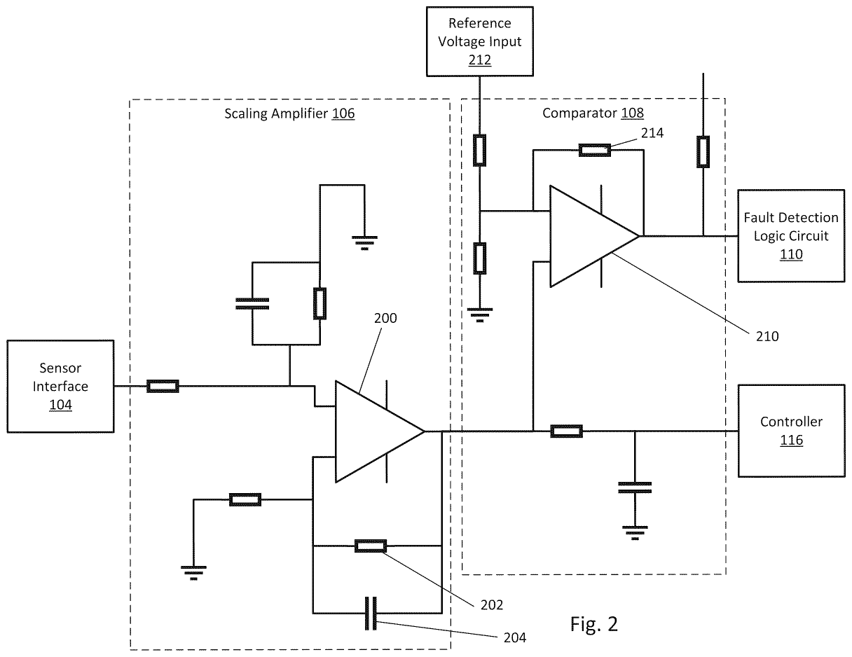

Scaling amplifiers 106 are circuits each configured to proportionally scale the voltage of a respective sensor output from the respective sensor interface 104 such that the voltage from the scaling amplifier is suitable for use by the respective comparator 108. A scaling amplifier 106 can be provided for each sensor interface 104 included in fault monitoring circuit 100. Scaling amplifiers 106 include one or more operational amplifiers and suitable resistors, capacitors, connections to voltages, and the like such that the gain of the operational amplifier scales the voltage from the sensor output to a range suitable for input into the respective comparator 108. In an embodiment, the gain of each scaling amplifier 106 can be selected to scale the voltage to a value where the sensor output received at sensor interface 104 is above a reference voltage of the respective comparator 108 when the sensor output is indicative of healthy operations, and below the reference voltage when the sensor output is indicative of a fault, or vice versa. In an embodiment, scaling amplifiers 106 can further be connected to controller 116, such that the scaled voltages can be received at controller 116, for example at an analog to digital converter included therein. In an embodiment, the gain for the operational amplifiers is selected such that the scaled voltage output from scaling amplifiers 106 is in a range from 0 to 5 volts DC. A non-limiting example of a circuit for scaling amplifier 106 is shown in FIG. 2 and described in further detail below. While three scaling amplifiers are shown in FIG. 1, more or fewer scaling amplifiers can be provided to provide a scaling amplifier 106 corresponding to each of the sensor interfaces 104.

Comparators 108 are each configured to receive a voltage from a respective one of the scaling amplifiers 106 and a reference voltage, and to output a voltage indicative of a logic level based on a comparison of the received voltage from scaling amplifier 106 and the reference voltage. The reference voltage can be a fixed voltage. The reference voltage can be a predetermined value based on the characteristics of voltages from sensors 102 as scaled by the respective scaling amplifier 106 and the characteristics indicative of faults. Comparators 108 can be configured such that the comparators 108 exhibit hysteresis, having one threshold to drive change in the output of comparator 108 from healthy operations to the fault state and a different threshold to change the output of comparator 108 from the fault state to healthy operations. Hysteresis can prevent constant switching between healthy and fault states, for example maintaining a fault state once the fault state has been detected. The hysteresis exhibited by comparators 108 can provide stability and avoid rapid switching between healthy and fault states, for example due to noise, transient conditions, operations near fault limits, and the like. The comparators 108 can be operational amplifier circuits, for example as described below and shown in FIG. 2. While three comparators 108 are shown in FIG. 1, more or fewer comparators 108 can be provided to provide a comparator 108 corresponding to each of the scaling amplifiers 106.

Fault detection logic circuit 110 is a circuit including one or more logic gates configured to receive the logic levels output from comparators 108, and based on the received logic levels, output a master logic level signal. Fault detection logic circuit 110 includes logic gates capable of receiving each of the voltages from the respective comparators 108. In an embodiment, the fault detection logic circuit 110 can include a plurality of AND gates, such that detection of a fault being indicated by the output from any of comparators 108 results in a master logic level signal indicative of a fault. In an embodiment, fault detection logic circuit 110 can receive a logic level output by the controller 116.

Gate driver 112 can be a gate driver connected to the device monitored by fault monitoring circuit 100, such as inverter 114. Gate driver 112 can provide a drive signal such as a pulse-wave modulation (PWM) signal for a high-power transistor such as a metal oxide semiconductor field effect transistor (MOSFET) of the device. Gate driver 112 is configured to receive a master logic signal from fault detection logic circuits 110 and, when the master logic signal indicates a fault, the gate driver is configured to implement a remedial action in response to the fault. The remedial action can be, for example, modifying the output of gate driver 112 to shut down or alter the operations the device monitored by fault monitoring circuit 100, for example by ceasing or altering the PWM signal provided to the MOSFET.

In an embodiment, the master logic level signal from fault detection logic circuit 110 can be provided to a controller, such as controller 116, and the controller can be operated to implement remedial actions such as shutting down the device or system through suitable software when the master logic level signal is indicative of a fault.

Inverter 114 is an example of a power electronics device capable of being monitored and controlled by the fault monitoring circuit 100. In embodiments, fault monitoring circuit 100 can be applied to other devices such as other power electronics. Inverter 114 can be controlled based on the output of gate driver 112. For example, the gate driver 112 can be connected to one or more metal oxide semiconductor field effect transistor MOSFETs of the inverter 114 to trigger shut down or adjust operation of the inverter 114 when the gate driver 112 receives the master logic level signal indicative of a fault. In an embodiment, inverter 114 is a component of another device or system such as a hydraulic power pack.

Controller 116 is a controller configured to receive the outputs of sensors 102 or scaled sensor outputs from scaling amplifier 106, and to determine, using software included in the controller 116, whether a fault is present. The controller 116 and software used thereby can be standard fault detection software for use in power electronics. The controller 116 can include any suitable one or more processors and memories to store and execute the software instructions to perform fault detection based on measurements by the sensors 102. Controller 116 can be a controller included in the device monitored by fault monitoring circuit 100, for example being a controller of a hydraulic power pack, inverter 114, or the like. The controller 116 can be used for fault detection in parallel with fault monitoring circuit 100. In an embodiment, controller 116 can output a logic level to the fault detection logic circuit 110, the logic level indicative of whether a fault has been determined at controller 116. The logic level can be received at one of the logic gates of fault detection logic circuit 110 and used in the determination of a fault at the fault detection logic circuit 110 and the corresponding operation of gate driver 112. In an embodiment, controller 116 can be connected to gate driver 112 to direct responses to faults detected by the controller 116. For example, gate driver 112 can be controlled based on detection of a fault by either of fault monitoring circuit 100 or the controller 116. In an embodiment, controller 116 is configured to detect the same faults as detected by fault monitoring circuit 100, for example to provide redundancy in detection of and response to faults. In an embodiment, controller 116 can be configured to detect at least some faults different from the faults detected by fault monitoring circuit 100, for example to provide more comprehensive detection and response to faults.

FIG. 2 shows a circuit diagram for examples of scaling amplifier 106 and comparator 108 according to an embodiment. Each respective sensor interface 104 can be connected to a respective scaling amplifier 106 and comparator 108 such as the example circuits shown in FIG. 2.

The scaling amplifier 106 includes operational amplifier 200 having suitable connections to ground and connected with respective resistor 202 and capacitor 204. Resistor 202 and capacitor 204 are selected to achieve the desired gain for scaling amplifier 106 to scale the signal from sensor interface 104 to a suitable voltage for comparator 108. In the embodiment shown in FIG. 2, the output of operational amplifier 200 is connected to comparator 108 and also to controller 116. A resistor-capacitor filter (R-C filter) can be included in the connection of the output of operational amplifier 200 to the controller 116.

Comparator 108 includes operational amplifier 210, reference voltage input 212, and resistor 214. The positive feedback to operational amplifier 210 through resistor 214 in the circuit for comparator 108 can provide hysteresis in the response characteristics of comparator 108, thus requiring one threshold to drive change in the output of comparator 108 from healthy operations to the fault state and a different threshold to change the output of comparator 108 from the fault state to healthy operations. The hysteresis provided by comparator 108 increases the stability of the logical output of comparator 108, thus avoiding rapid switching between the logical states for healthy operation or presence of a fault based on noise, transient conditions, operation near the threshold for a fault, or the like. The output of the comparator 108 can be connected to the fault detection logic circuit 110.

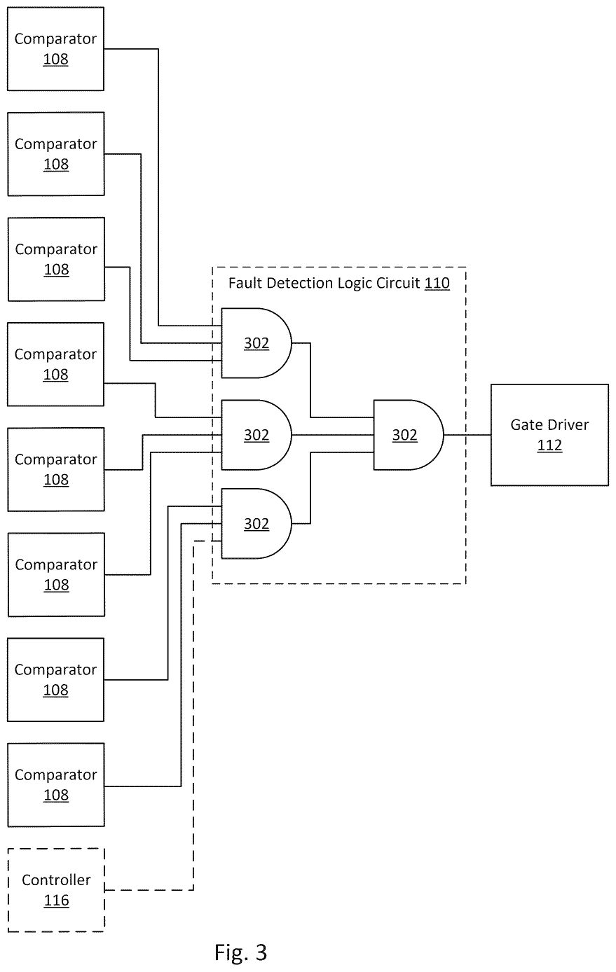

FIG. 3 shows a circuit diagram for an example fault detection logic circuit 110 according to an embodiment. Fault logic circuit 110 includes a plurality of logic gates 302. The logic gates 302 are configured to receive the outputs from each of the comparators 108 of the fault monitoring circuit 100 including fault detection logic circuit 110. The logic gates 302 can be AND gates where the healthy operation outputs are a logical “1”, such that any presence of a fault, a logical “0” in the fault detection logic circuit 110, would lead the logic gate to return a “0” indicative of the presence of a fault as the master logic level. The logic gates 302 can be included in numbers sufficient to accept an output from each of comparators 108, and connected such that the outputs of all comparators 108 are used to determine one master logic level signal that is output from fault detection logic circuit 110. The master logic level can be a “1” indicative of healthy operations based on the outputs of all of the sensors 102, or a “0” when a fault is determined based on a scaled output of at least one of the sensors 102. The output of the final logic gate 302 providing the master logic level can be, for example, connected to gate driver 112.

In an embodiment, an input to fault logic circuit 110 can be a logic signal output by the controller 116. The logic signal output by the controller 116 can be based on the determination of a fault by the controller 116, for example based on the scaled voltages received at controller 116 from scaling amplifiers 106. The logic signal output by the controller 116 can be a logical “1” when the controller 116 does not determine a fault to be present, and a logical “0” when the controller 116 determines the presence of a fault. The logic signal output by the controller 116 can be handled by the logic gates 302 in the same manner as outputs from the comparators 108, such that when the controller 116 outputs a logical “0,” the master logic level is a “0” indicating a fault, and when the controller 116 outputs a logical “1,” the master logic level can be a “0” or a “1” depending on whether a fault is indicated by any of the outputs of the comparators 108 connected to logic gates 302.

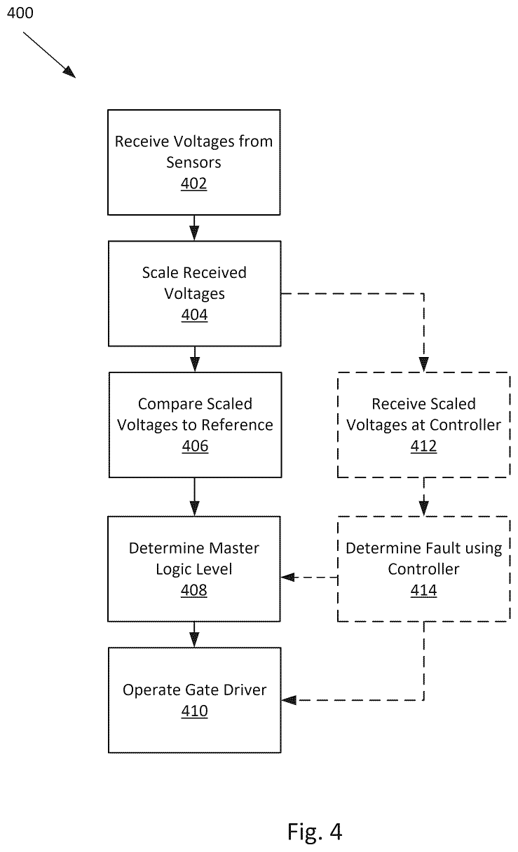

FIG. 4 shows a method of fault detection according to an embodiment. Method 400 includes receiving voltages from sensors at respective interfaces 402, scaling the received voltages using respective scaling amplifier circuits 404, comparing the scaled voltages to respective reference voltages 406, determining a master logic level based on the comparison outputs at one or more logic gate circuits at 408, and operating a gate driver based on the master logic level at 410. Optionally, the method 400 can further include receiving the scaled voltages at a controller 412 and determining a fault using the controller at 414.

Method 400 is a method for hardware-based fault detection and triggering of remedial actions. In an embodiment, software-based fault detection can optionally be performed in parallel with the hardware-based fault detection in method 400, for example through receiving the scaled voltages at a controller 412 and determining a fault using the controller at 414. Method 400 can be iterated, for example being performed periodically or continuously to monitor for the occurrence of faults or end of fault conditions during operations of a system such as a motor controller or a hydraulic power pack incorporating such a motor controller. In an embodiment, the method 400 can be performed in other power electronics systems, for example to control an inverter to detect and respond to faults in such a system. Method 400 can be performed using hardware components arranged according to the fault detection circuit 100 discussed above and shown in FIG. 1.

Voltages are received from sensors at respective interfaces at 402. The voltages are voltages indicative of measured parameters as detected by sensors, such as voltage, current, temperature, and/or pressure sensors. The sensors can be selected to measure parameters indicative of a fault in a device or system, such as a hydraulic power pack, an inverters, controllers thereof, or the like. The voltages can be received at 402 at a respective interface for each sensor, such as a wire or other electrical connection connecting the output of the sensor to a respective scaling amplifier circuit.

The received voltages can be scaled using respective scaling amplifier circuits at 404. The scaling amplifier circuits can be, for example, scaling amplifiers 106 as described above and shown in FIGS. 1 and 2. The scaling of the received voltages can be a proportional scaling of the received voltage to a suitable range of voltages for input into comparators, such as the comparators 108 as described above and shown in FIGS. 1 and 2. The scaling at 404 can be performed using an operational amplifier circuit configured to have a predetermined gain selected to scale the output of the respective sensor to the suitable range of voltages, for example through selection of the capacitor and resistor used in the amplifier circuit. The voltages as scaled at 404 can then be provided to respective comparators.

The scaled voltages are compared to respective reference voltages 406 using respective comparator circuits, such as comparators 108 as described above and shown in FIGS. 1 and 2. The comparison at 406 can output the reference voltage when the scaled voltage is indicative of healthy operations, and to output another voltage when the scaled voltage is indicative of the presence of a fault. The comparators 108 can exhibit hysteresis, for example by including positive feedback as discussed above and shown in FIG. 2. Hysteresis can result in one threshold for changing in the output of the comparator from healthy operations to the fault state and a different threshold for changing the output of the comparator from the fault state to healthy operations, thereby avoiding rapid switching between healthy and fault states based on noise, transient conditions, operations close to the fault threshold, or the like. The output of each of the comparators can be provided to respective inputs of a logic gate circuit.

A master logic level is determined based on the comparisons at a logic gate circuit at 408. The logic gate circuits can include a plurality of hardware logic gates configured to receive each of the comparator outputs from the comparisons at 406 and to determine the master logic level based on each of the outputs. The logic gate circuit used to determine the master logic level at 408 can be logic gate circuit 110 as discussed above and shown in FIGS. 1 and 3. The logic gate circuit can include one or more logic gates, such that all comparator outputs can be received as inputs and to output one master logic level. The logic gates used to determine the master logic level can be AND gates where a logical “1” is representative of comparator output indicating healthy operations and a logical “0” is representative of comparator output indicative of a fault. In an embodiment, when any comparator output determined at 406 indicates a fault, the master logic level determined at 408 is a “0 ,” and when no fault is indicated, the master logic level determined at 408 is a “1” based on the arrangement of AND gates of the logic gate circuit.

A gate driver is operated based on the master logic level signal at 410. The gate driver can be a gate driver of the device or system being monitored for faults according to method 400, such as a hydraulic power pack, an inverter, controllers thereof, or the like. The gate driver can receive the master logic level as a signal from the logic gate circuit determining the master logic level at 408, for example the logic gate circuit 110. The gate driver can operate the device or system at 410 according to normal operations when the master logic level is indicative of healthy operations, for example by providing suitable PWM signals or the like to one or more high-power transistors of the system or device, such as a MOSFET included therein. The gate driver can modify or halt operation of the device or system at 410 when the master logic level signal indicates that the master logic level indicates a fault, for example by altering or ceasing the PWM signal or the like.

Optionally, the method 400 can further include receiving the scaled voltages at a controller 412 and determining a fault using the controller at 414. The controller can be, for example, controller 116 discussed above and shown in FIG. 1. The scaled voltages can be received at the controller at 412 through connections from each scaling amplifier circuit to the controller. The scaled voltages can be filtered, for example through an R-C filter included in the connection of the scaling amplifier circuit to the controller. The voltages received at 412 can be used by controller 414 to determine whether a fault is present, for example by using suitable software to process the received voltages to make the determination of whether a fault is present. The determination of the fault at 414 can be performed in parallel with the determination of faults by comparing the scaled voltages at 406 and determining the faults based on comparison outputs at 408. In an embodiment, the determination of the fault at 414 can be provided as a logic level provided to the logic gate circuit for use in the determination of the master logic level at 408. In an embodiment, the operation of the gate driver at 410 can be based on the determination of a fault either by the one or more logic gate circuits at 408 or the determination of a fault by the controller at 414.

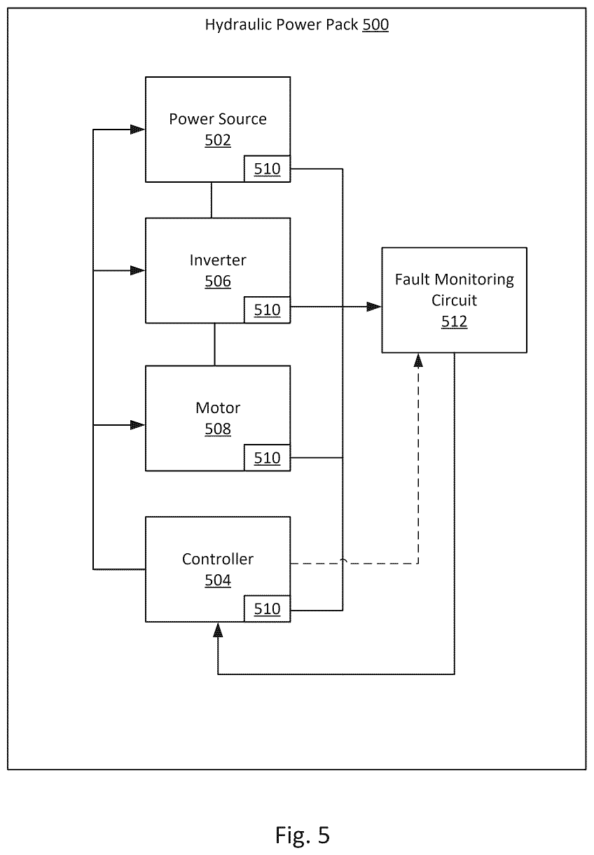

FIG. 5 shows a schematic of a hydraulic power pack according to an embodiment. Hydraulic power pack 500 includes power source 502, controller 504, inverter 506, and motor 508. Sensors 510 can be provided at one or more of power source 502, controller 504, inverter 506, and/or motor 508. Fault monitoring circuit 512 can provide a master logic level based on the outputs of the sensors 510.

Hydraulic power pack 500 can be an electrically powered hydraulic power pack including power source 502. Power source 502 can be an electrical power source, such as one or more batteries, configured to provide power to operate the hydraulic power pack 500. Controller 504 is configured to control operations of the hydraulic power pack 500, including supply of power from power source 502, operation of inverter 506, and/or operation of motor 508. Inverter 506 can be provided to convert direct current (DC) power from power source 502 to suitable alternating current (AC) power to drive operation of motor 508. Motor 508 can drive one or more pumps to provide pressure to a fluid during operation of hydraulic power pack 500.

One or more sensors 510 can be provided to measure conditions at one or more of the power source 502, controller 504, inverter 506, and/or motor 508. Each of the sensors 510 can be configured to measure conditions indicative of potential faults at the respective component where the sensor 510 is provided, such as a voltage, a current, a temperature, a pressure, or the like and output a voltage indicative of the measured condition.

Fault monitoring circuit 512 can be configured to receive the respective voltages output by the one or more sensors 510 and generate a master logic level indicative of healthy operations or presence of a fault based on the received voltages. Fault monitoring circuit 512 can be a hardware circuit configured to output the master logic level as a signal when receiving the voltages from the one or more sensors. An example embodiment of the fault monitoring circuit 512 is fault monitoring circuit 100 as described above and shown in FIG. 1. The fault monitoring circuit 512 can be connected, for example, to controller 504, such that the controller 504 direct remedial actions when a fault is indicated by the master logic level. Alternatively or additionally, the fault monitoring circuit 512 can be connected directly to one or more of power source 502, inverter 506, and/or motor 508 to provide the master logic level, and remedial action such as alteration or termination of operations can be performed at the respective power source 502, inverter 506, and/or motor 508, for example through operation of a gate driver included therein. In an embodiment, controller 504 can be configured to determine the presence of a fault, for example, based on software executed by the controller 504. In an embodiment, the determination of a fault at controller 504 can be provided to the fault monitoring circuit 512 as a logic level input into logic gates used to determine the master logic level of fault monitoring circuit 512.

### Aspects of the Disclosure

It is understood that any of aspects 1-13 can be combined with any of aspects 13-20.

Aspect 1. A fault monitoring circuit, comprising:
one or more sensor interfaces;
one or more scaling amplifiers, each scaling amplifier connected to a respective sensor interface of the one or more sensor interfaces, each of the one or more scaling amplifiers configured to output a scaled voltage proportional to a voltage received from the respective sensor interface;

one or more comparators each configured to receive the scaled voltage from one of the one or more scaling amplifiers and to output a logic level based on the scaled voltage, the logic level indicative of health or a fault;

a logic gate circuit configured to receive the logic level of each of the one or more comparators and to output a master logic level signal.

Aspect 2. The fault monitoring circuit according to aspect 1, wherein the one or more comparators exhibit hysteresis.

Aspect 3. The fault monitoring system according to aspect 1 or aspect 2, further including one or more sensors connected to the one or more sensor interfaces.

Aspect 4. The fault monitoring system according to aspect 3, wherein the one or more sensors include at least one of a voltage sensor, a current sensor, and a temperature sensor.

Aspect 5. The fault monitoring system according to aspect 4, wherein the one or more sensors include a voltage sensor, a current sensor, and a temperature sensor.

Aspect 6. The fault monitoring system according to aspect 4 or aspect 5, wherein the one or more sensors further include a pressure sensor.

Aspect 7. The fault monitoring system according to any of aspects 1-6, further comprising a controller configured to receive the scaled voltages from the one or more scaling amplifiers and determine a fault based on the scaled voltages.

Aspect 8. The fault monitoring system according to aspect 7, wherein the controller is configured to operate a gate driver based on the determination of the fault.

Aspect 9. The fault monitoring circuit according to any of aspects 1-8, further comprising a gate driver.

Aspect 10. The fault monitoring system according to aspect 9, wherein the gate driver is configured to control an inverter.

Aspect 11. A motor controller unit comprising the fault monitoring system according to aspect 10 and the inverter.

Aspect 12. A hydraulic power pack including the motor controller unit according to aspect 11.

Aspect 13. A method, comprising:
receiving one or more voltages at a respective one or more sensor interfaces;
scaling the received one or more voltages using a respective one or more scaling amplifier circuits to output one or more scaled voltages;
comparing the one or more scaled voltages to a respective one or more reference voltages using a respective one or more comparators to output a respective one or more logic levels;
determining a master logic level using one or more logic gate circuits based on the one or more logic levels; and
operating a gate driver based on the master logic level.

Aspect 14. The method according to aspect 13, further comprising measuring one or more voltages, temperatures, or currents using one or more respective sensors to generate the one or more voltages.

Aspect 15. The method according to aspect 13 or aspect 14, further comprising measuring a pressure using a pressure sensor to generate one of the one or more voltages.

Aspect 16. The method according to any of aspects 13-15, wherein the one or more comparators are configured to exhibit hysteresis when outputting the respective one or more logic levels.

Aspect 17. The method according to any of aspects 13-16, wherein operating the gate driver controls operation of an inverter.

Aspect 18. The method according to aspect 17, wherein the inverter is included in a motor control unit.

Aspect 19. The method according to any of aspects 13-18, further comprising receiving the one or more scaled voltages at a controller and determining a fault using the controller.

Aspect 20. The method according to aspect 19, further comprising operating the gate driver based on an output from the controller.

Having described the preferred aspects and implementations of the present disclosure, modifications and equivalents of the disclosed concepts may readily occur to one skilled in the art. However, it is intended that such modifications and equivalents be included within the scope of the claims which are appended hereto.

What is claimed is:

1. A fault monitoring circuit, comprising:
one or more sensor interfaces;
one or more scaling amplifiers, each scaling amplifier connected to a respective sensor interface of the one or more sensor interfaces, each of the one or more scaling amplifiers configured to output a scaled voltage proportional to a voltage received from the respective sensor interface;
one or more comparators each configured to receive the scaled voltage from one of the one or more scaling amplifiers and to output a logic level based on the scaled voltage, the logic level indicative of health or a fault;
a logic gate circuit configured to receive the logic level of each of the one or more comparators and to output a master logic level signal.

2. The fault monitoring circuit of claim 1, wherein the one or more comparators exhibit hysteresis.

3. The fault monitoring system of claim 1, further including one or more sensors connected to the one or more sensor interfaces.

4. The fault monitoring system of claim 3, wherein the one or more sensors include at least one of a voltage sensor, a current sensor, and a temperature sensor.

5. The fault monitoring system of claim 4, wherein the one or more sensors include a voltage sensor, a current sensor, and a temperature sensor.

6. The fault monitoring system of claim 4, wherein the one or more sensors further include a pressure sensor.

7. The fault monitoring system of claim 1, further comprising a controller configured to receive the scaled voltages from the one or more scaling amplifiers and determine a fault based on the scaled voltages.

8. The fault monitoring system of claim 7, wherein the controller is configured to operate a gate driver based on the determination of the fault.

9. The fault monitoring circuit of claim 1, further comprising a gate driver.

10. The fault monitoring system of claim 9, wherein the gate driver is configured to control an inverter.

11. A motor controller unit comprising the fault monitoring system of claim 10 and the inverter.

12. A hydraulic power pack including the motor controller unit of claim 11.

13. A method, comprising:
receiving one or more voltages at a respective one or more sensor interfaces;
scaling the received one or more voltages using a respective one or more scaling amplifier circuits to output one or more scaled voltages;
comparing the one or more scaled voltages to a respective one or more reference voltages using a respective one or more comparators to output a respective one or more logic levels;
determining a master logic level using one or more logic gate circuits based on the one or more logic levels; and
operating a gate driver based on the master logic level.

14. The method of claim 13, further comprising measuring one or more voltages, temperatures, or currents using one or more respective sensors to generate the one or more voltages.

15. The method of claim 13, further comprising measuring a pressure using a pressure sensor to generate one of the one or more voltages.

16. The method of claim 13, wherein the one or more comparators are configured to exhibit hysteresis when outputting the respective one or more logic levels.

17. The method of claim 13, wherein operating the gate driver controls operation of an inverter.

18. The method of claim 17, wherein the inverter is included in a motor control unit.

19. The method of claim 13, further comprising receiving the one or more scaled voltages at a controller and determining a fault using the controller.

20. The method of claim 19, further comprising operating the gate driver based on an output from the controller.
